(19) United States
(12) Patent Application Publication
(10) Pub. No.: US 2002/0093091 A1
(43) Pub. Date: Jul. 18, 2002

(54) Method of fabricating a ground-ball bonding structure without trapped air for tape ball grid array application

(75) Inventors: Chien-Ping Huang, Hsinchu (TW); Zong-Da Ho, Taichung (TW); Che-Jung Chang, Taichung (TW)

Correspondence Address: EDWARDS & ANGELL, LLP, 130 Water Street, Boston, MA, 02109-4280, US

(73) Assignee: Siliconware Precision Industries Co., Ltd., Taichung (TW)

(21) Appl. No.: 09/838,521

(22) Filed: Apr. 19, 2001

(30) Foreign Application Priority Data
Jan. 18, 2001 (TW) 90101177

(51) Int. Cl. H01L 21/44; H01L 21/48; H01L 21/50; H01L 23/34; H01L 23/52

(52) U.S. Cl. 257/706; 438/122; 438/613; 257/707; 257/738

(57) ABSTRACT

A method for fabricating a ground-ball bonding structure on a TBGA package is proposed, which is characterized by the forming of a plurality of air vents around the ground-ball pad and cut all the way into the tape until reaching the bottommost surface of the tape. During solder-reflow process, this allows the trapped air in the via hole due to solder material being filled into the via hole to the outside atmosphere during solder-reflow process. Compared to the prior art, since the proposed method allows substantially no air-filled voids to be left in the via hole, the resulted ground ball would be fully collapsed against the heat sink and therefore coplanarized with respect to the signal ball. The coplanarity of the overall ball grid array would allow the TBGA package to be mounted properly onto a printed circuit board during SMT (Surface Mount Technology) process. In addition, the proposed method allows a reliable bonding between the ground ball and the heat sink thus assuring the grounding effect of the resulted TBGA package.

### BACKGROUND OF THE INVENTION

1. Field of the Invention

This invention relates to integrated circuit packaging technology, and more particularly, to a method of fabricating a solder-ball bonding structure without causing air trap for TBGA (Tape Ball Grid Array) application.

2. Description of Related Art

BGA (Ball Grid Array) is an advanced type of integrated circuit packaging technology which is characterized in the use of a substrate whose front side is mounted with a semiconductor chip and whose back side is mounted with a grid array of solder balls. During SMT (Surface Mount Technology) process, the BGA package can be mechanically bonded and electrically coupled to a printed circuit board (PCB) by means of these solder balls.

TBGA (Tape Ball Grid Array) is an improved type of BGA technology which is characterized by the use of a tape as the based for the mounting of semiconductor chip and the attachment of solder balls thereon. The TBGA technology allows the overall package body to be made more compact in size.

FIG. 1 is a schematic sectional diagram showing a conventional TBGA package configuration (note that FIG. 1 is a simplified schematic diagram showing only a small number of components and those parts related to the invention; the actual layout on the TBGA package would be much more complex).

As shown, this TBGA package configuration includes: (a) a heat sink 10; (b) a semiconductor chip 11 mounted on the heat sink 10 and whose grounding point 5 is connected to the heat sink 10; (c) a tape 20, typically a polyimide tape, which is adhered to the heat sink 10 by means of an adhesive layer 21, and which is formed with a via hole 22 to expose a selected part of the heat sink 10; (d) a ring-shaped ground-ball pad 31 formed over the tape 20 and around the via hole 22; and a signal-ball pad 32 located at a predetermined position over the tape 20 (the actual layout would include a plurality of ground-ball pads and signal-ball pads); (e) a solder mask 40 having a predefined masking pattern that masks all the areas on the tape 20 other than the ground-ball pad 31 and the signal-ball pad 32; and (f) a ball grid array 50 including a ground ball 51 attached to the ground-ball pad 31 and a signal ball 52 attached to the signal-ball pad 32.

In the foregoing TBGA package configuration, since the ground ball 51 is directly bonded through the via hole 22 to the heat sink 10, it can serve as an external grounding point for the semiconductor chip 11; i.e., when the TBGA package is mounted to a printed circuit board (not shown) by means of the ball grid array 50, the semiconductor chip 11 can be connected to the PCB's grounding lines via the ground ball 51.

As the TBGA package is completed, it is desired that the resulted ball grid array 50 should have high coplanarity; i.e., the ground ball 51 and the signal ball 52 should be substantially coplanarized to the same plane P₀ as illustrated in FIG. 1.

However, by conventional fabrication method, the ground ball 51 might be undesirably uncoplanarized with respect to the signal ball 52 due to the existence of trapped air inside the via hole 22. The cause of this problem is depicted in the following with reference to FIGS. 2A-2F which depict the procedural steps involved in the conventional method for fabricating the ground ball 51.

Referring to FIG. 2A and FIG. 2B, the TBGA package is constructed on a heat sink 10 and a tape 20 adhered to the heat sink 10 by means of an adhesive layer 21. Further, the tape 20 is formed with a via hole 22 to expose a selected part of the heat sink 10. To allow ground-ball attachment, a ring-shaped ground-ball pad 31 is formed over the tape 20 and around the via hole 22; and a solder mask 40 is formed over the tape 20 to mask all the areas on the tape 20 other than the inner part of the ground-ball pad 41.

Referring further to FIG. 2C, in the next step, a solder-pasting process is performed to paste a solder material through the solder mask 40 into the via hole 22 until the pasted solder 51a is substantially leveled to the topmost surface of the solder mask 40. During this solder-pasting process, however, some air-filled voids 60 would be undesirably left near the bottom of the via hole 22.

Referring further to FIG. 2D, in the next step, a first solder-reflow process is performed to reflow the pasted solder 51a so as to make the pasted solder 51a wetted to the unmasked inner part of the ground-ball pad 31. During this process, however, the air-filled voids 60 would nevertheless stay near the bottom of the via hole 22.

Refer ring further to FIG. 2E, in the next step, a solder flux 51b is applied to the exposed surface of the reflowed solder paste 51a; and then, a solder ball 51c is attached to the solder flux 51b.

Referring further to FIG. 2F, in the next step, a second solder-reflow process is performed, wherein the solder ball 51c is melted together with the solder flux 51b and the solder paste 51a into an integral body of solder serving as the intended ground ball 51.

Through the foregoing steps, however, due to the existence of the air-filled voids.60 near the bottom of the via hole 22, the resulted ground ball 51 would be undesirably elevated to a greater height that makes the ground ball 51 uncoplanarized with respect to the signal ball 52, as indicated by the two uncoplanarized planes P₀, P₁ in FIG. 2F.

The uncoplanarity of the overall ball grid array 50 would adversely affect the subsequent mounting of the resulted TBGA package over a printed circuit board (PCB). In addition, the existence of the air-filled voids 60 in the via hole 22 would likely cause a failed bonding between the ground ball 51 and the heat sink 10, thus degrading the grounding effect of the packaged semiconductor chip 11.

Related patents include, for example, U.S. Pat. No. 5,397,921 entitled “TAB GRID ARRAY”; U.S. Pat. No. 5844,168 entitled “MULTI-LAYER INTERCONNECT STRUCTURE FOR BALL GRID ARRAYS”; and U.S. Pat. No. 6,020,637 entitled “BALL GRID ARRAY SEMICONDUCTOR PACKAGE”, to name just a few. However, none of these patents teach a solution to the aforementioned problem oftrapped air in the via hole where ground ball is formed.

### SUMMARY OF THE INVENTION

It is therefore an objective of this invention to provide an improved method for fabricating a ground-ball bending structure on TBGA package, which can help to prevent the existence of trapped, air in the via hole where a ground ball is formed so as to allow high coplanarity between ground balls and signal balls.

It is another objective of this invention to provide an improved method for fabricating a solder-ball bonding structure on TBGA package, which can help to prevent the existence of trapped air in the via hole where a ground tall is formed so as to provide reliable bonding between the ground balls and the heat sink.

In accordance with the foregoing and other objectives, the invention proposes an improved method for fabricating a solder-ball bonding structure on TBGA package.

The method of the invention comprises the following steps: (1) forming a via hole in the tape to expose a selected part of the heat sink; (2) forming a ring-shaped ground-ball pad over the tape and around the via hole; the ring-shaped ground-ball pad being formed with a plurality of air vents spaced substantially at equal radial intervals around the via hole and cut all the way into the tape until reaching the heat sink; (3) forming a solder mask over the tape while unmasking the ring-shaped ground-ball pad; (4) performing a solder-pasting process to paste a solder material through the solder mask into the via hole; and during the solder-pasting process, air-filed voids are undesirably left in the via hole; (5) performing a first solder-reflow process to reflow the pasted solder in the via hole; and during the first solder-reflow process, the air in the air-filled voids would substantially drawn via the air vents to outside atmosphere; (6) attaching a solder ball by means of a solder flux to the pasted solder in the via hole; and (7) performing a second solder-reflow process so as to reflow the solder ball, the solder flux, and the solder paste into an integral body of solder wetted to the ring-shaped ground-ball pad to serve as a ground ball connected to the heat sink.

Compared to the prior art, since the method of the invention allows substantially no air-filled voids to be left in the via hole, the resulted ground ball would be filly collapsed against the heat sink and therefore coplanarized with respect to the signal ball. The coplanarity of the overall ball grid array would allow the TBGA package to be mounted properly over a printed circuit board during SMT (Surface Mount Technology) process. In addition, the method of the invention allows a reliable bonding between the ground ball and the heat sink, thus assuring the grounding effect of the resulted TBGA package.

### BRIEF DESCRIPTION OF DRAWINGS

The invention can be more fully understood by reading the following detailed description of the preferred embodiments, with reference made to the accompanying drawings, wherein:

FIG. 1 (PRIOR ART) is a schematic sectional diagram showing a conventional TBGA package configuration;

FIGS. 2A-2F (PRIOR ART) are schematic sectional diagrams used to depict a conventional method for fabricating a ground-ball bonding structure on TBGA package;

FIGS. 3A-3G are schematic sectional diagrams used to depict the method according to the invention for fabricating a ground-ball bonding structure on TBGA package;

FIGS. 4A-4C are schematic diagrams showing various other embodiments of the invention; and

FIGS. 5A-5B are schematic diagrams shown in top view of the dimensional restrictions of the air vents provided by the invention.

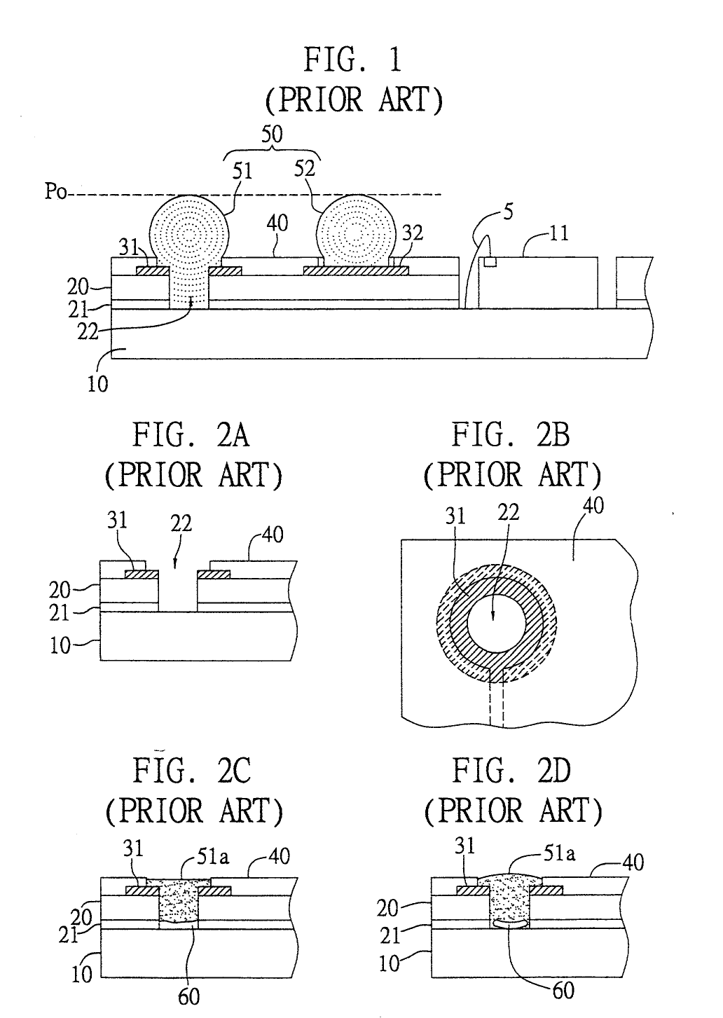

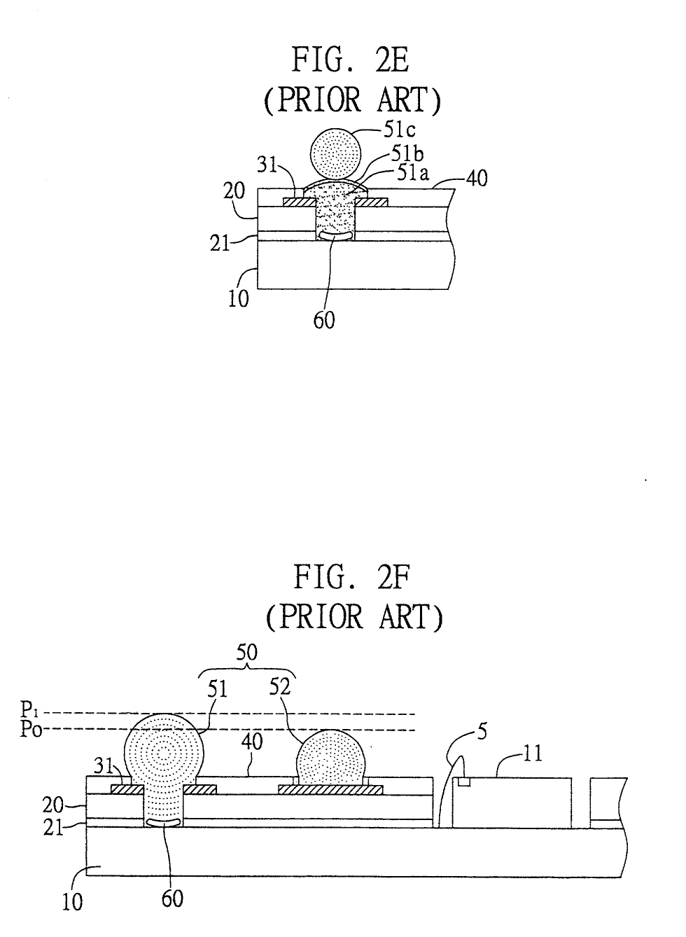

### DETAILED DESCRIPTION OF PREFERRED EMBODIMENTS

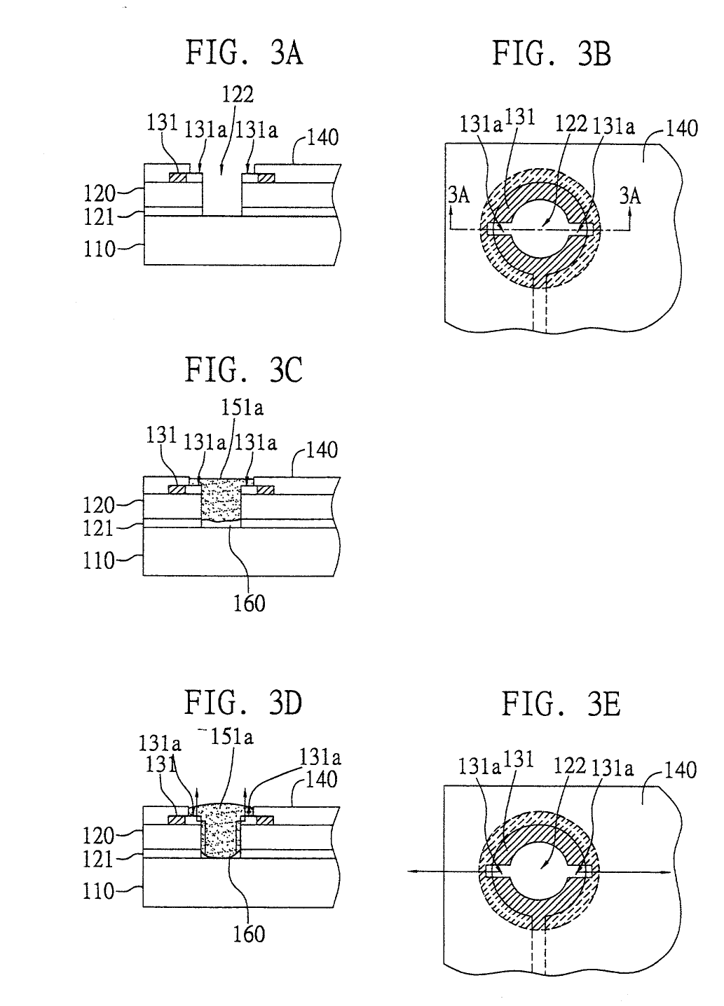

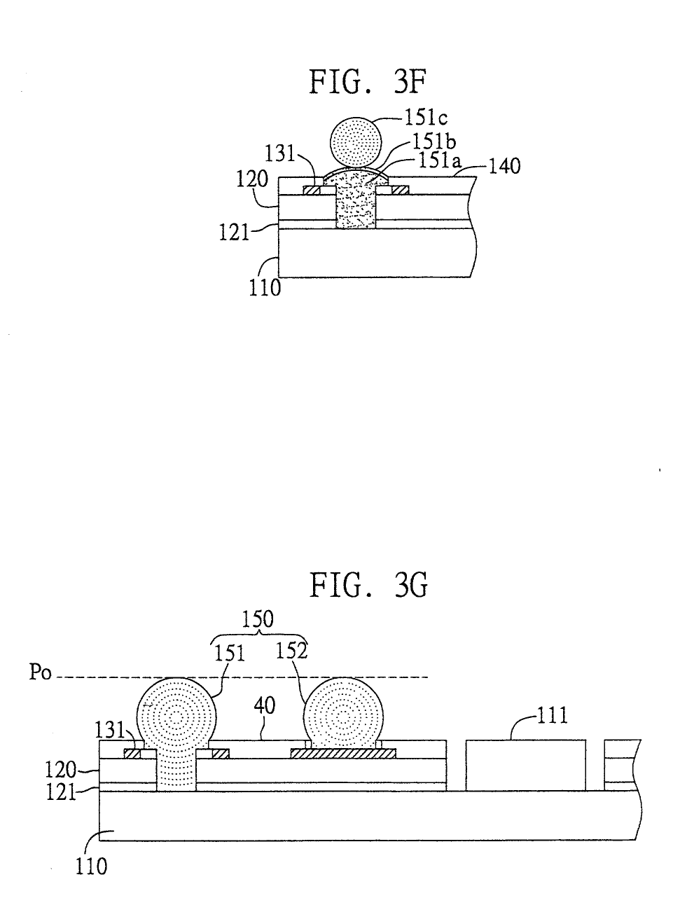

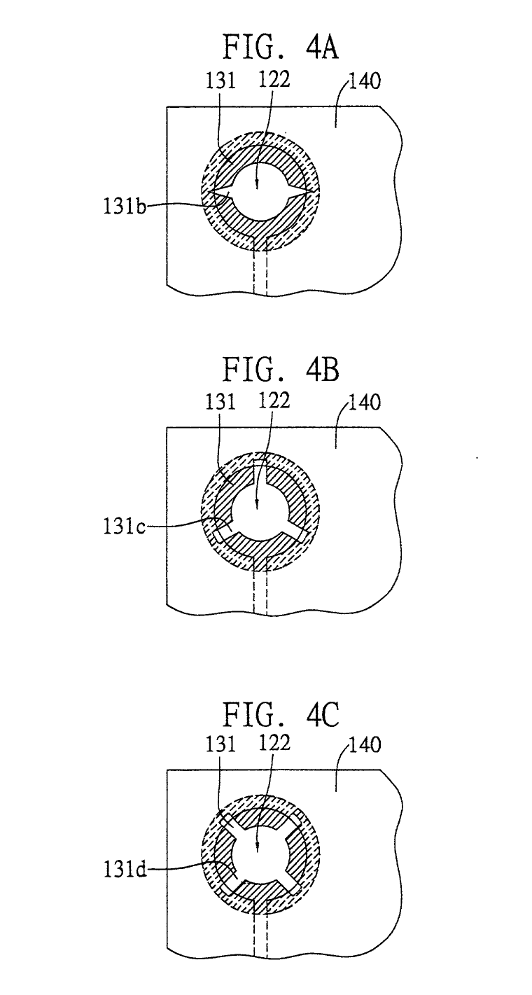

The method according to the invention the invention for fabricating a solder-ball bonding structure on TBGA package is disclosed in full details in the following with reference to FIGS. 3A-3G and FIGS. 4A-4C.

Referring first to FIG. 3A together with FIG. 3B, the TBGA package is constructed on a heat sink 110 and a tape 120 adhered to the heat sink 110 by means of an adhesive layer 121. Further, the tape 120 is formed with a via hole 122 to expose a selected part of the heat sink 110. To allow ground-ball attachment, a ring-shaped ground-ball pad 131 is formed over the tape 120 and around the via hole 122; and a solder mask 140 is formed over the tape 120 to mask all the areas on the tape 120 other than the inner part of the ring-shaped ground-ball pad 131.

As shown in FIG. 3B, it is a characteristic feature of the invention that the ring-shaped ground-ball pad 131 is formed with a plurality of air vents 131a spaced substantially at equal radial intervals around the ground-ball pad 131, and the air vents 131a are cut all the way into the tape 120 until reaching the bottom surface of the heat sink 110. In this embodiment, the air vents 131a are rectangularly shaped in cross section and spaced at 180□ radial intervals around the ring-shaped ground-ball pad 131.

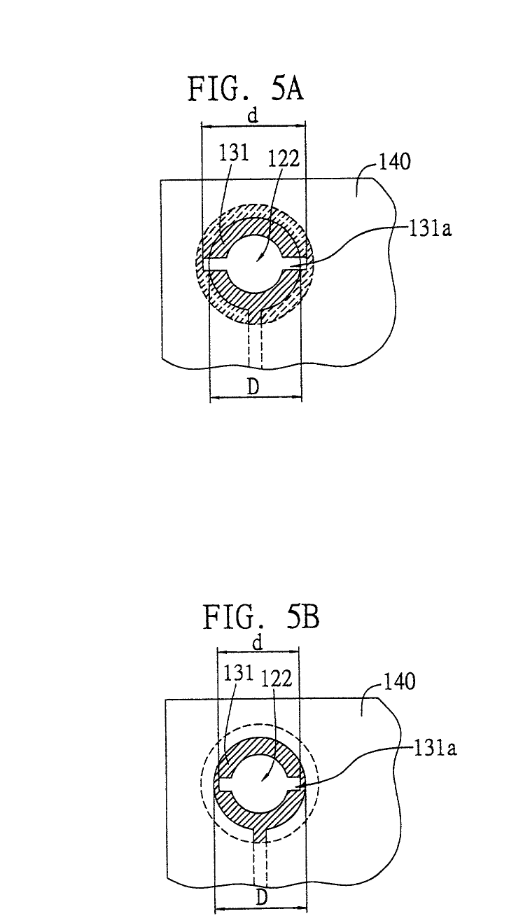

As shown in FIG. 5A, by the invention, it is required to dimension the air vents 131a in such a manner that the distance d between the respective outermost edges thereof should be equal to or greater than the diameter D of the via hole 122, so as to allow the outermost ends of the air vents 131a to extend to the beneath of the solder mask 140. Otherwise, if d<D, as illustrated in FIG. 5B, it would make the ground-ball pad 131 nevertheless a continuous ring similar to the prior art and not an interspaced ring required by the invention.

In the embodiment of FIG. 3B, the ground-ball pad 131 includes two air vents 131a which are each substantially rectangularly-shaped in cross section and are arranged at 180□ intervals on the periphery of the ground-ball pad 131.

FIGS. 4A-4C are schematic diagrams showing various other embodiments of the ring-shaped ground-ball pad 131. In the embodiment of FIG. 4A, the ring-shaped ground-ball pad 131 is formed with two air vents 131b which are triangularly shaped in cross section and spaced at 180□ radial intervals around the ring-shaped ground-ball pad 131. In the embodiment of FIG. 4B, the ring-shaped ground-ball pad 131 is formed with three air vents 131c which are rectangularly shaped in cross section and spaced at 120□ radial intervals around the ring-shaped ground-ball pad 131. In the embodiment of FIG. 4C, the ring-shaped ground-ball pad 131 is formed with four air vents 131d which are rectangularly shaped in cross section and spaced at 90□ radial intervals around the ring-shaped ground-ball pad 131. Beside these embodiments, various other shapes for the air vents are possible.

Referring further to FIG. 3C, in the next step, a solder-pasting process is performed to paste a solder material through the solder mask 140 into the via hole 122 until the pasted solder 151a is substantially leveled to the topmost surface of the solder mask 140. As mentioned in the background section of this specification, during this solder-pasting process, some air-filled voids 160 would be undesirably left near the bottom of the via hole 122.

Referring further to FIG. 3D together with FIG. 3E, in the next step, a first solder-reflow process is performed to reflow the pasted solder 151a and make it wetted to the unmasked inner part of the ring-shaped ground-ball pad 131. During this process, since the polyimide-made tape 120 is solder-unwettable, the pasted solder 151a in melted state would reflow freely downwards against the bottom of the heat sink 110 and thereby draw the air in the air-filled voids 160 through the air vents 131a to the outside atmosphere , (the air path is indicated by the two arrows in FIG. 3D and FIG. 3E). As a result, as the first solder-reflow process is completed, there would substantially exist no air-filled voids near the bottom of the via hole 122.

Referring further to FIG. 3F, in the next step, a solder flux 151b is applied to the exposed surface of the reflowed solder paste 151a; and then, a solder ball 151c is attached to the solder flux 11b.

Referring further to FIG. 3G, in the next step, a second solder-reflow process is performed, wherein the solder ball 151c is melted together with the solder flux 151b and the solder paste 151a into an integral body of solder serving as the intended ground ball 151. The ground ball 151 together with the nearby signal ball 152 constitute a ball grid array 150.

Through the foregoing steps, since there would substantially exist no air-filled voids near the bottom of the via hole 122, the resulted ground ball 151 would be fully collapsed against the heat sink 110 and therefore coplanarized with respect to the signal ball 152. This allows the overall ball grid array 150 to be coplanarized to the same plane P₀. In addition, since there would substantially exist no air-filled voids near the bottom of the via hole 122 is formed, the bonding between the ground ball 151 and the heat sink 110 would be more reliable, thus assuring the grounding effect of the packaged semiconductor chip 111

Conclusion

In conclusion, the invention provides an improved method for fabricating a ground-ball bonding structure on TBGA package, which is characterized by the forming of a plurality of air vents around the ground-ball pad and cut all the way into the tape until reaching the bottommost surface of the tape. During solder-reflow process, this allows the trapped air near the bottom of the via hole to be drawn via these air vents to the outside atmosphere. Compared to the prior art, since the method of the invention allows substantially no air-filled voids to be left in the via hole, the resulted ground ball would be fully collapsed against the heat sink and therefore coplanarized with respect to the signal ball. The coplanarity of the overall ball grid array would allow the TBGA package to be mounted properly over a printed circuit board during SMT (Surface Mount Technology) process. In addition, the method of the invention allows a reliable bonding between the ground ball and the heat sink, thus assuring the grounding effect of the resulted TBGA package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a ground-ball bonding structure on a TBGA package constructed on a heat sink and a tape;
the method comprising the steps of:
(1) forming a via hole in the tape to expose a selected part of the heat sink;
(2) forming a ring-shaped ground-ball pad over the tape and around the via hole; the ring-shaped ground-ball pad being formed with a plurality of air vents spaced substantially at equal radial intervals around the via hole and cut all the way into the tape until reaching the heat sink;
(3) forming a solder mask over the tape while unmasking the ring-shaped ground-ball pad;
(4) performing a solder-pasting process to paste a solder material through the solder mask into the via hole; and during the solder-pasting process, air-filled voids are undesirably left in the via hole;
(5) performing a first solder-reflow process to reflow the pasted solder in the via hole; and during the first solder-reflow process, the air in the air-filled voids would substantially drawn via the air vents to outside atmosphere, thereby allowing the pasted solder to substantially fill up the entire void space of the via hole;
(6) attaching a solder ball by means of a solder flux to the pasted solder in the via hole; and
(7) performing a second solder-reflow process so as to reflow the solder ball, the solder flux, and the solder paste into an integral body of solder wetted to the ring-shaped ground-ball pad to serve as a ground ball connected to the heat sink.

2. The method of claim 1, wherein in said step (2), the ground-ball pad is formed with two air vents spaced substantially at 180□ intervals around the via hole.

3. The method of claim 1, wherein in said step (2), the ground-ball pad is formed with three air vents spaced substantially at 120□ intervals around the via hole.

4. The method of claim 1, wherein in said step (2), the ground-ball pad is formed with four air vents spaced substantially at 90□ intervals around the via hole.

5. A TBGA package configuration, comprising:
(a) a heat sink;
(b) a tape mounted over the heat sink and formed with a via hole to expose a selected part of the heat sink
(c) a ring-shaped ground-ball pad formed over the tape and around the via hole; the ring-shaped ground-ball pad being formed with a plurality of air vents spaced substantially at equal radial intervals around the via hole and cut all the way into the tape until reaching the heat sink; the air vents being used to facilitate the drainage of trapped air in the via hole due to solder material being filled into the via hole to outside atmosphere during solder-reflow process; and
(d) a solder mask formed over the tape while unmasking the ring-shaped ground-bah pad.

6. The TBGA package configuration of claim 5, wherein the ring-shaped ground-ball pad is formed with two air vents spaced substantially at 180□ intervals around the via hole.

7. The TBGA package configuration of claim 5, wherein the ring-shaped ground-ball pad is formed with three air vents spaced substantially at 120□ intervals around the via hole.

8. The TBGA package configuration of claim 5, wherein the ring-shaped ground-ball pad is formed with four air vents spaced substantially at 90□ intervals around the via hole.
